(19) United States
(12) Patent Application Publication
(10) Pub. No.: US 2014/0218006 A1
(43) Pub. Date: Aug. 7, 2014

(54) WATER HEATER ANODE ROD DEPLETION SENSING

(71) Applicant: GENERAL ELECTRIC COMPANY, Schenectady, NY (US)

(72) Inventors: Michelle Diana Gross, Louisville, KY (US); Jonathan D. Nelson, Louisville, KY (US); Brett Alan Farris, Louisville, KY (US); William A. Baker, Louisville, KY (US)

(73) Assignee: GENERAL ELECTRIC COMPANY, Schenectady, NY (US)

(21) Appl. No.: 13/760,368

(22) Filed: Feb. 6, 2013

(51) Int. Cl. G01R 19/00

(52) U.S. Cl. CPC G01R 19/0092
USPC 324/71.4

(57) ABSTRACT

The present subject matter relates to methodologies for sensing anode rod depletion. Consumers generally are not concerned with monitoring consumption of protective anode rods incorporated within water heaters. The present subject matter provides automatic monitoring of anode rod depletion and provides the consumer with notification of rod depletion beyond a predetermined amount. The principles of Faraday's Law are used to calculate anode weight loss by conversion of measured and accumulated current.

### FIELD OF THE INVENTION

The present subject matter relates to appliance protection functionality. More specifically, the present subject matter relates to methods and systems for providing various anode rod depletion operational functionalities for water heaters.

### CROSS REFERENCE TO RELATED APPLICATIONS

The present subject matter is related to GE docket #264098 entitled “Anode Depletion Sensor Hardware Circuit” and GE docket #264099 entitled “Anode Depletion Sensor Algorithm” both filed concurrently herewith, assigned to the owner of the present subject matter, and incorporated herein for all purposes.

### BACKGROUND OF THE INVENTION

Most modern water heaters are constructed of a steel tank with a glass lining. A sacrificial anode rod is often inserted in the tank to protect any exposed steel from corroding and causing the tank to leak. Sacrificial anode rods can continue protecting a water heater tank from as little as a few years to many years. They are typically made from an alloy of metals with a higher electronegativity than the steel tank. The most common sacrificial metals from which an anode is made are magnesium and aluminum.

Currently, water heater use and care manuals instruct the consumer to remove the anode rod from the water heater every couple of years to inspect it and replace it if most of it has depleted. Checking an anode rod is an inconvenience for several reasons. Either a plumber must be called, or the consumer must check it themselves by turning off the water, partially draining the plumbing and tank, and removing the anode rod. Removing the anode may be difficult if the fitting has rusted in place or if there is not enough overhead clearance to fully remove the rod.

In view of these known issues, it would, therefore, be advantageous if a sensor that alerts the consumer that their anode rod needs to be replaced were associated with water heaters. Such a sensor would have the added advantage of saving the consumer time and money. With such a sensor in place, consumers that are aware that the anode rod needs to be checked periodically will not have the inconvenience of either calling a plumber every couple years or having to remove the anode rod themselves. On the other hand, consumers who never check the anode rod will be alerted when their anode is close to being depleted. In those instances, instead of having the tank corrode and leak, the consumer can purchase a new anode rod instead of a whole new water heater.

### BRIEF DESCRIPTION OF THE INVENTION

Aspects and advantages of the presently disclosed subject matter will be set forth in part in the following description, or may be apparent from the description, or may be learned through practice of the presently disclosed subject matter.

The present subject matter relates to a method for alerting a consumer of water heater anode rod depletion. According to such method anode rod galvanic current is periodically measured and the number of electrons transferred from the anode is calculated. The number of transferred electrons is then converted to anode weight and the converted anode weight is compared to an initial anode weight. If anode weight loss is above a predetermined amount an alarm signal is activated.

These and other features, aspects and advantages of the presently disclosed subject matter will become better understood with reference to the following description and appended claims. The accompanying drawings, which are incorporated in and constitute a part of this specification, illustrate embodiments of the presently disclosed subject matter and, together with the description, serve to explain the principles of the presently disclosed subject matter.

### BRIEF DESCRIPTION OF THE DRAWINGS

A full and enabling disclosure of the presently disclosed subject matter, including the best mode thereof, directed to one of ordinary skill in the art, is set forth in the specification, which makes reference to the appended figures, in which:

FIG. 1 provides a diagram of exemplary corrosion reactions of a magnesium bar in water;

FIG. 2 provides a diagram of exemplary water heater tank corrosion reactions; and

FIG. 3 provides a diagram of exemplary reactions occurring with a magnesium bar placed in a water filled water heater tank.

Repeat use of reference characters throughout the present specification and appended drawings is intended to represent same or analogous features or elements.

### DETAILED DESCRIPTION OF THE INVENTION

Reference now will be made in detail to embodiments of the presently disclosed subject matter, one or more examples of which are illustrated in the drawings. Each example is provided by way of explanation of the presently disclosed subject matter, not limitation thereof. In fact, it will be apparent to those skilled in the art that various modifications and variations can be made in the presently disclosed subject matter without departing from the scope or spirit of the presently disclosed subject matter. For instance, features illustrated or described as part of one embodiment can be used with another embodiment to yield a still further embodiment. Thus, it is intended that the presently disclosed subject matter covers such modifications and variations as come within the scope of the appended claims and their equivalents

Many factors play a role in the rate of depletion of the sacrificial anode rod. Temperature, pressure, exposed surface area of both the tank and anode rod, and especially water conditions, all influence the rate of depletion. Water conditions such as low pH and high chlorine can attack magnesium and cause it to corrode faster. Public water systems are regulated for chemicals and pH, reducing the range of factors that can affect anode rod depletion. However, a significant number of other factors still exist. Water hardness is typically proportional to water conductivity and has a significant impact on depletion rate. Water hardness varies widely from region to region and is heavily influenced by water sources, such as lakes, rivers, and wells.

The addition of a water softener does not lower the depletion rate of a water heater's anode rod. The ion exchange of the water softener means that ions are still present in the water, maintaining or even increasing conductivity. Reducing hardness also means that there will be less build-up of deposits on the surface of the anode rod and on the inner surface of the tank, meaning more easily accessible surface area to continue the galvanic circuit.

With such a diverse amount of water conditions, it is difficult to predict exactly when a sacrificial anode rod has been consumed without removing it from the water heater and inspecting it. Several solutions exist for determining if an anode rod is depleted. There are physical methods, such as sensors buried in or connected to cavities in the anode material. Other methods are possible, and involve reading a potential or current in the water or anode caused by corrosion of the metals.

In accordance with the presently disclosed subject matter, during the galvanic reaction, a current can be detected and measured at the interface of the anode and tank as electrons move from one metal to the other. The current can be processed in many ways in order to detect when the anode needs to be replaced, including looking for a change in current, a threshold number, or a cessation of current. Unfortunately, there are several problems with these methods. Looking for a change in current over time cannot account for large variations in water conditions, such as the addition or removal of a water softener. A hard threshold cannot account for the large starting variation seen across different water conditions, and may signal falsely in a low-current start condition. If the sensor algorithm is checking for the point in time when current stops, the tank will not be protected during the interval between the detection of no current and the consumer replacing the anode rod.

However, a solution to these problems can be found in Faraday's Laws of Electrolysis, which iterate that the current produced by an electrode is directly proportional to the mass of the material that has been depleted and to its equivalent weight. With this knowledge, in accordance with the presently disclosed subject matter, the current produced by the anode rod can be summed over time to determine the weight of the sacrificial anode rod that has been depleted. If the starting weight is known, then the consumer can be flagged (alerted) to replace the anode rod before the anode is fully depleted, and can even be given an indication of how much has been depleted. One factor affecting such a method, however, is that anode rods are not 100% efficient. As the anode metal aggressively depletes to protect the cathode metal, parts of the anode metal will also be lost to localized corrosion. The presently disclosed subject matter provides not only an explanation of the chemistry behind anode depletion and an exemplary method of detection, but also discloses methods for establishing efficiency values of particular magnesium alloy anodes presently in use in selected water heaters.

On a high level, the presently disclosed subject matter involves reading (measuring) current produced by the anode, converting the measured current to an amount of anode material lost, and totalizing the amount of material lost over time. The algorithms (see the above cross referenced applications) account for the correction factor, or efficiency, of the anode material, and, optionally, process power outages with a real-time clock and with an average of before and after current readings.

One of the main advantages behind totalizing galvanic current is that the anode is passive. The galvanic current is produced by simply electrically attaching the anode, for example, a magnesium or aluminum alloy anode rod, to the cathode (the water heater steel tank) and immersing the two in an electrolyte (water). In a traditional water heater, the electrical connection is made through the anode cap screwed into the tank port.

Galvanic current can be read with any type of anode as long as a galvanic reaction is occurring. Reading current requires that an anode be electrically isolated from the metal it is protecting, but still submerged in the electrolyte. The passive galvanic current is forced through a circuit to read current and then returned to ground, the tank in this scenario. The current-reading circuit does not need an external power source in order to maintain the connection between the anode and the cathode (tank) to keep the passive galvanic circuit active. The circuit allows the anode to continually protect the tank, even in the absence of power, providing a clear advantage over anode rod solutions that require a constantly available power source in order to maintain operation.

Those of ordinary skill in the art will appreciate that there are many insulated fitting designs possible. It is important that an electrically insulated fitting be incorporated into the design of an anode rod. In addition, fitting designs must allow a means to connect to the anode material in order to read the current it produces.

Different types of sacrificial anodes are allowed by governing agencies to be installed in water heaters, and all will provide some level of cathodic protection to the tank. Each type is defined by the composition of metals that make up the alloy of the anode rod. Different compositions of alloys will have different current capacities, the capacity of the material to cathodically protect the metal to which it is attached. Each composition will also have its own efficiency. Efficiency is the ratio of anode weight lost to cathodic protection compared to the weight lost to corrosion and other mechanisms that may cause part of the material to break away.

Anode rods with magnesium as the main metal component in the composition will have a lower efficiency. This is due in part to the electronegativity of magnesium. Magnesium is very reactive, readily giving up 2 electrons to its environment. As such, localized reactions can and do occur at the surface of the magnesium anode rod, without exposing current to a sensor designed to read the galvanic current between the anode and tank.

In accordance with the presently disclosed subject matter, it has been found that a correction factor is needed to account for weight losses associated with localized reactions. Research of magnesium anodes indicates efficiencies near 50%. As a part of the development of the presently disclosed subject matter, field tests were performed with different water supplies to empirically confirm the efficiency factor of the anodes. These test results indicated efficiencies averaged to 45%.

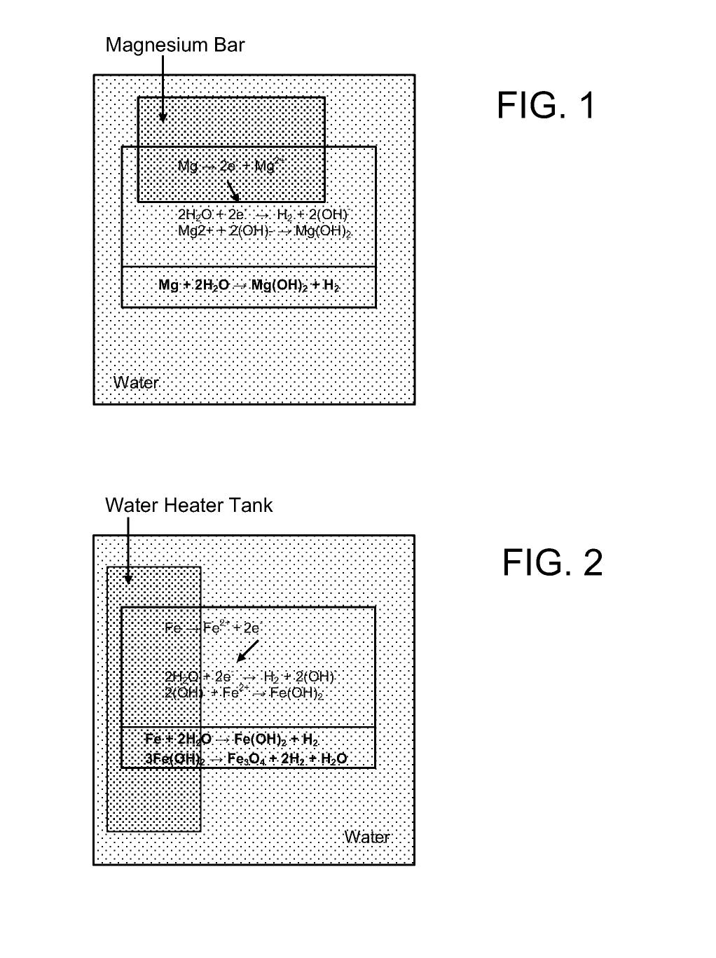

With present reference to FIGS. 1 and 2, it will be appreciated that most metals left in water will eventually corrode to some degree, even without a driving galvanic potential. As illustrated in FIG. 1, magnesium (Mg) will often corrode into magnesium hydroxide, Mg(OH)₂, which will eventually dissolve into the water, exposing the next layer of metal. With reference to FIG. 2, iron (Fe), such as included in the steel tanks of water heaters, will often form an oxide layer on the metal surface.

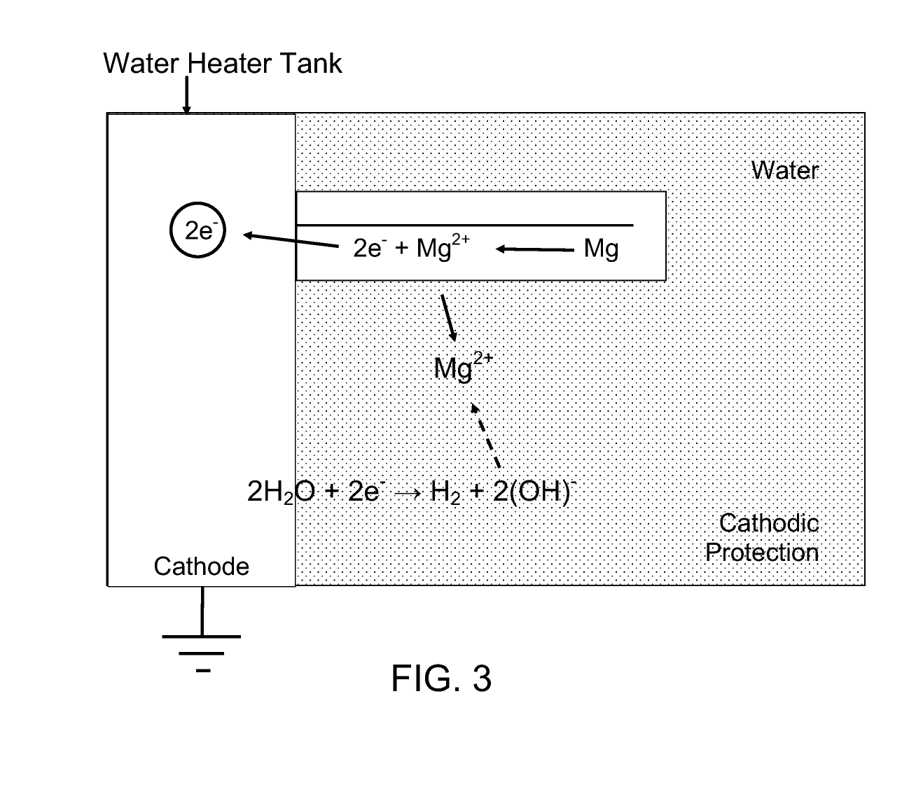

With present reference to FIG. 3, it is seen that when physically connected and in the presence of water, dissimilar metals behave very differently than when they are not connected. In the case of magnesium and iron, a galvanic circuit is created. In a galvanic reaction between magnesium and iron, the corrosion of the iron slows down significantly or even stops, while the rate of corrosion of the magnesium speeds up. This is due to the higher anodic potential of magnesium than iron.

Faraday's Laws of Electrolysis allow the correlation of current to mass. Current is a flow of electrons, which when measured and processed will equate to a precise number of electrons moving over a given time period. If the chemical make-up of the anode metal is known, then the number of anode valence electrons migrating to the tank will also be known. From a current reading (measurement), one can calculate the number of transferred electrons, and thus the number of atoms that have been consumed during a given time period. With the number of atoms, one can then calculate the anode weight loss

For example, an anode rod made of magnesium transfers two valence electrons to the steel tank for every one atom of magnesium lost. Since the atomic weight of magnesium is known, the weight of lost magnesium can be calculated for a given number of transferred electrons. While the measured current and calculated weight values can be processed many different ways, one example is as follows. The algorithm controlling the current-sensing circuit is designed to process the measured galvanic current and convert that value into weight lost while factoring in a value for efficiency. Storing a running total of depleted weight allows the software to flag (send a signal to) a consumer when a predetermined level of depletion has been reached. Availability of such information then allows the consumer to replace the anode rod before it is fully depleted thereby allowing the tank to last much longer than it would without replacing the anode rod. In alternative embodiments of the present subject matter, the algorithm controlling the current-sensing circuit may also, or alternatively, provide the consumer with information regarding the amount of anode depletion even before the predetermined level of depletion has been reached.

Based on field and lab experiments, it is evident that combining anode efficiency with Faraday's Laws of Electrolysis provides a valid method of determining how much anode material has been depleted in a given amount of time. Further, while the present discussion has related to the use of generally known materials presently employed in the construction of anode rods, the present subject matter provides direction for implementing appropriate modifications to the evaluation algorithm should an anode rod with a new alloy be chosen. Any and all such variations are fully contemplated by the present disclosure.

This written description uses examples to disclose the invention, including the best mode, and also to enable any person skilled in the art to practice the invention, including making and using any devices or systems and performing any incorporated methods.

The patentable scope of the presently disclosed subject matter is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method for calculating water heater anode rod depletion, comprising:
periodically measuring anode rod galvanic current;
converting current to number of electrons transferred from the anode to the water heater tank;
calculating the number of anode atoms sacrificed to cathodic protection from the number of transferred electrons from the anode rod to the water heater tank; and
calculating the anode weight from the number of sacrificed anode atoms.

2. A method as in claim 1, wherein the anode rod corresponds to one of magnesium (Mg) alloy or aluminum (Al) alloy.

3. A method as in claim 1, wherein the signal provides an indication that the anode rod needs to be replaced.

4. A method as in claim 1, further comprising:
producing a signal indicative of the amount of anode rod depletion.

5. A method as in claim 1, wherein conversion of the number of transferred electrons to anode weight includes applying an anode rod correction factor.

6. A method as in claim 1, wherein calculating the number of electrons transferred is conducted over a predetermined time period.

7. A method as in claim 6, wherein the predetermined time is established by a time reading.

8. A method as in claim 7, wherein the time is read from an independent energy backed up clock.

9. A method as in claim 1, further comprising:
electrically isolating the anode rod from the water heater tank.

10. A method as in claim 1, wherein calculating the number of electrons transferred from the anode is based on averaged current readings.

11. A method as in claim 1, further comprising:
comparing the sacrificed anode weight to an initial anode weight; and
activating a signal if anode weight loss is above a predetermined amount.
